(19) United States
(12) Patent Application Publication
(10) Pub. No.: US 2024/0098998 A1
(43) Pub. Date: Mar. 21, 2024

(54) SEMICONDUCTOR MEMORY DEVICE AND METHOD OF MANUFACTURING SEMICONDUCTOR MEMORY DEVICE

(71) Applicant: Kioxia Corporation, Tokyo (JP)

(72) Inventors: Saori MATSUSHITA, Yokkaichi Mie (JP); Tomonari SHIODA, Nagoya Aichi (JP); Takanori YAMANAKA, Yokkaichi Mie (JP); Ryota FUJITSUKA, Yokkaichi Mie (JP)

(21) Appl. No.: 18/457,645

(22) Filed: Aug. 29, 2023

(30) Foreign Application Priority Data
Sep. 20, 2022 (JP) 2022-149191

(51) Int. Cl. H10B 43/27

(52) U.S. Cl. CPC H10B 43/27

(57) ABSTRACT

A semiconductor memory device includes: a stacked body in which a plurality of conductive layers and a plurality of insulating layers are stacked one by one alternately; and a pillar that extends in the stacked body in a stacking direction of the stacked body and includes a memory cell formed at each of intersections with the plurality of conductive layers, in which the pillar includes a semiconductor layer extending in the stacking direction, a silicon oxynitride layer covering a side wall of the semiconductor layer, a silicon nitride layer covering a side wall of the silicon oxynitride layer, and a silicon oxide layer covering a side wall of the silicon nitride layer, in which the silicon oxynitride layer has a hydrogen concentration of 1×10²⁰ atm/cc or less in terms of average value.

### CROSS-REFERENCE TO RELATED APPLICATION

This application is based upon and claims the benefit of priority from Japanese Patent Application No. 2022-149191, filed Sep. 20, 2022, the entire contents of which are incorporated herein by reference.

### FIELD

Embodiments described herein relate generally to a semiconductor memory device and a method of manufacturing a semiconductor memory device.

### BACKGROUND

In a three-dimensional nonvolatile memory, for example, a pillar penetrates a stacked body in which a plurality of conductive layers are stacked, and a memory cell is formed at each of intersections between the plurality of conductive layers and the pillar. In the memory cell, a valence band barrier of a tunnel insulating layer is reduced to improve erasing characteristics of data. On the other hand, the leakage current in the low and medium field range increases as a result of the reduction in the valence band barrier.

### DESCRIPTION OF THE DRAWINGS

FIG. 1 is a schematic diagram illustrating a schematic configuration of a semiconductor memory device according to at least one embodiment.

FIGS. 2A and 2B are cross-sectional views illustrating an example of a configuration of a pillar of the semiconductor memory device according to at least one embodiment.

FIGS. 3A to 3F are cross-sectional views in a Y direction sequentially illustrating a part of a procedure in a method of manufacturing the semiconductor memory device according to at least one embodiment.

FIGS. 4A to 4F are cross-sectional views in the Y direction sequentially illustrating a part of the procedure in the method of manufacturing the semiconductor memory device according to at least one embodiment.

FIGS. 5A to 5F are cross-sectional views in the Y direction sequentially illustrating a part of the procedure in the method of manufacturing the semiconductor memory device according to at least one embodiment;

FIGS. 6A and 6C are schematic diagrams illustrating a formation mechanism of a tunnel insulating layer according to at least one embodiment.

FIGS. 7A and 7B are schematic diagrams illustrating a mechanism when a voltage is applied to the tunnel insulating layer according to at least one embodiment.

FIG. 8 is a graph illustrating a relationship between each of tunnel insulating layers according to Example and Comparative Example and a leakage current.

FIG. 9 is a graph illustrating a relationship between the leakage current of each of the tunnel insulating layers according to Example and Comparative Example and a temperature.

FIG. 10 is a graph illustrating a hydrogen content in a silicon oxynitride layer simulating each of the tunnel insulating layers according to Example and Comparative Example.

### DETAILED DESCRIPTION

Embodiments provide a semiconductor memory device and a method of manufacturing a semiconductor memory device, in which improvement of erasing characteristics and a reduction in a leakage current of a memory cell can be simultaneously achieved.

In general, according to at least one embodiment, a semiconductor memory device includes: a stacked body in which a plurality of conductive layers and a plurality of insulating layers are stacked one by one alternately; and a pillar that extends in the stacked body in a stacking direction of the stacked body and includes a memory cell formed at each of intersections with the plurality of conductive layers, in which the pillar includes a semiconductor layer extending in the stacking direction, a silicon oxynitride layer covering a side wall of the semiconductor layer, a silicon nitride layer covering a side wall of the silicon oxynitride layer, and a silicon oxide layer covering a side wall of the silicon nitride layer, in which the silicon oxynitride layer has a hydrogen concentration of 1×10²⁰ atm/cc or less in terms of average value.

Hereinafter, embodiments will be described in detail with reference to the drawings. The present disclosure is not limited to the following embodiments. In addition, components in the following embodiments include those that are easily conceivable by persons skilled in the art or substantial equivalents thereof.

Configuration Example of Semiconductor Memory Device

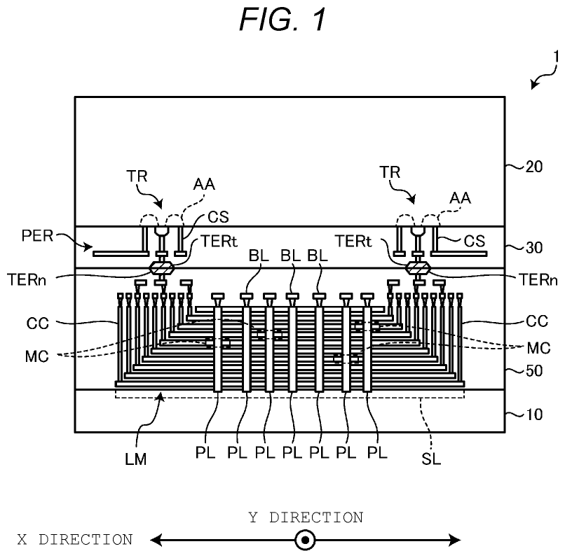

FIG. 1 is a schematic diagram illustrating a schematic configuration of a semiconductor memory device 1 according to the embodiment. As illustrated in FIG. 1, the semiconductor memory device 1 includes a stacked body LM and a peripheral circuit PER.

The stacked body LM has a structure in which a plurality of word lines are stacked on a source line SL through an insulating layer. The semiconductor memory device 1 includes a supporting substrate 10 that supports the stacked body LM. In this case, the supporting substrate 10 may be a semiconductor substrate, a ceramic substrate, a glass substrate, or the like, and the source line SL is disposed on a surface layer of the supporting substrate 10. When the supporting substrate 10 is the semiconductor substrate, the source line SL may be a diffusion layer or the like in which impurity of the surface layer of the supporting substrate 10 is diffused.

At opposite end portions of the stacked body LM in an X direction, the word lines are processed stepwise, and a contact CC is connected to each of steps of the word lines. An upper end of the contact CC is connected to an upper layer wiring or the like through a plug. The upper layer wiring is further connected to a terminal TERn through a plug. The terminal TERn is formed of, for example, copper (Cu).

In the stacked body LM, a plurality of pillars PL that penetrate the stacked body LM in a stacking direction and reach the source line SL are located in a matrix configuration. Each of the pillars PL includes a memory layer and a channel layer. In the channel layer of the pillar PL, a lower end is connected to the source line SL, and an upper end is connected to a bit line BL through a plug or the like. A memory cell MC is formed at an intersection between the pillar PL and the word line of the stacked body LM.

This way, the semiconductor memory device 1 is configured as, for example, a three-dimensional nonvolatile memory including the memory cells MC that are three-dimensionally located.

The stacked body LM, the contact CC, the plug, the upper layer wiring, the bit line BL, and the like are covered with an insulating layer 50. The terminal TERn is exposed to an upper surface of the insulating layer 50.

The peripheral circuit PER includes a plurality of transistors TR formed on the semiconductor substrate 20 and controls an electrical operation of the plurality of memory cells MC. The transistor TR is, for example, a complementary metal oxide semiconductor (CMOS) transistor and includes an active area AA that is a diffusion layer and the like disposed on a surface layer of the semiconductor substrate 20.

The transistor TR is connected to the upper layer wiring through a contact CS. The upper layer wiring is further connected to a terminal TERt through a plug. The terminal TERt is formed of, for example, copper (Cu).

The peripheral circuit PER including the transistor TR, the contact CS, the plug, and the like are covered with an insulating layer 30. The terminal TERt is exposed to an upper surface of the insulating layer 30.

The semiconductor memory device 1 has a configuration in which the insulating layer 50 that covers the stacked body LM and the insulating layer 30 that covers the peripheral circuit PER are joined. As a result, the terminal TERn exposed to the upper surface of the insulating layer 50 and the terminal TERt exposed to the upper surface of the insulating layer 30 are joined.

The configuration of the stacked body LM such as the pillar PL and the contact CC and the peripheral circuit PER are electrically connected through the terminals TERn and TERt. The peripheral circuit PER controls a write operation, a read operation, and the like of the memory cell MC, for example, by applying a predetermined voltage to the word line of the stacked body LM connected to the memory cell MC.

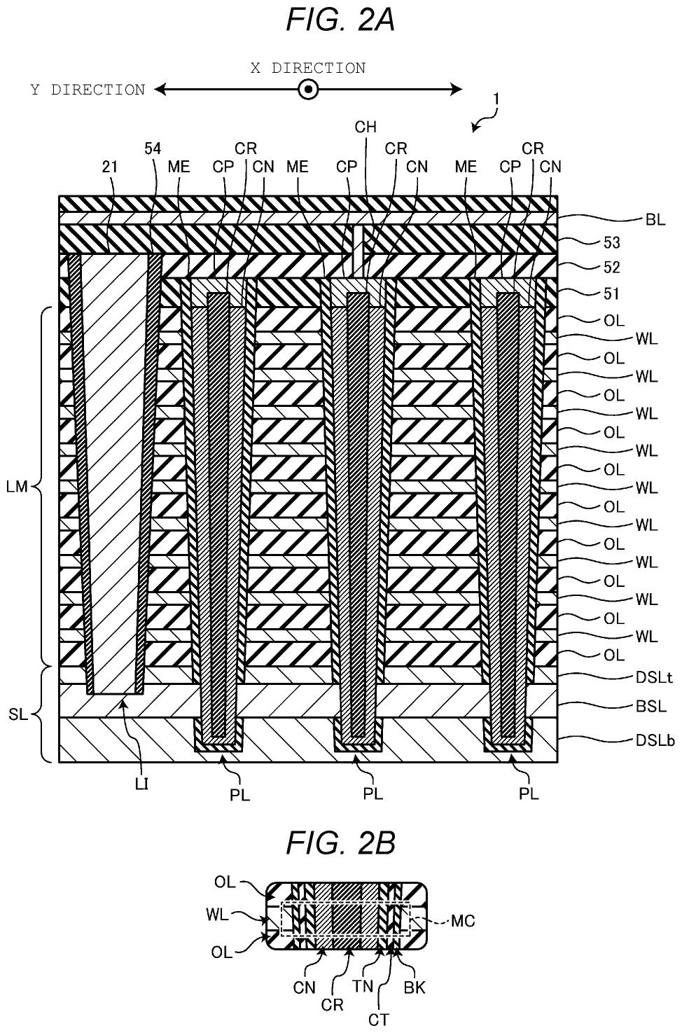

FIGS. 2A and 2B are cross-sectional views illustrating an example of a configuration of the pillar PL of the semiconductor memory device 1 according to the embodiment. FIG. 2A is a cross-sectional view in a Y direction illustrating an overall structure of the pillar PL of the semiconductor memory device 1. FIG. 2B is an enlarged cross-sectional view illustrating the pillar PL in the vicinity of the word line WL.

As illustrated in FIG. 2A, the semiconductor memory device 1 includes the source line SL, the stacked body LM, insulating layers 51 to 53, and the bit line BL as a configuration around the pillar PL. In the present specification, it is assumed that, for example, with respect to the pillar PL, a direction toward the source line SL corresponding to the source side is a downward direction of the semiconductor memory device 1 and a direction toward the bit line BL corresponding to the drain side is an upward direction of the semiconductor memory device 1.

The source line SL is provided below the stacked body LM and has a stacked structure in which a lower source line DSLb, an intermediate source line BSL, and an upper source line DSLt are stacked in order from the bottom side. The lower source line DSLb, the intermediate source line BSL, and the upper source line DSLt are, for example, conductive polysilicon layers. As described above, when the supporting substrate 10 (refer to FIG. 1) is, for example, the semiconductor substrate, at least a part of the source line SL may be configured with a part of the supporting substrate 10.

The stacked body LM has a configuration in which a plurality of word lines WL as a plurality of conductive layers and a plurality of insulating layers OL are stacked one by one alternately. The stacked body LM may include one or more select gate lines in a layer further above the word line WL of the uppermost layer. In addition, the stacked body LM may include one or more select gate lines in a layer further below the word line WL of the lowermost layer.

Each of the plurality of word lines WL is, for example, a tungsten (W) layer or a molybdenum (Mo) layer. The insulating layer OL is, for example, a silicon oxide (SiO₂) layer. More specifically, the plurality of word lines WL have a stacked structure of any of the above-described layers, a tungsten nitride (WN) layer, a molybdenum nitride (MoN) layer, a titanium nitride (TiN) layer, or the like. In addition, each of the plurality of word lines WL is surrounded by any of an aluminum oxide (AlO) layer, a hafnium oxide (HfO) layer, or a zirconium oxide (ZrO) layer, and a hafnium silicate (HfSiO) layer, a zirconium silicate (ZrSiO) layer, or the like, or a block layer having a stacked structure of some layers among the above-described layers.

In the example of FIG. 2A, nine word lines WL are provided in the stacked body LM. However, the number of layers of the word lines WL may be any number irrespective of the example of FIG. 2A.

The insulating layers 51 to 53 are stacked in this order on the stacked body LM. The insulating layers 51 to 53 are, for example, silicon oxide layers and configure a part of the insulating layer 50 (refer to FIG. 1). In the insulating layer 53, the bit line BL corresponding to the upper layer wiring of the pillar PL is provided.

In the stacked body LM, a plurality of plate-shaped contacts LI that extend in the stacked body LM in a stacking direction of the layers and extend in a direction along the X direction of the stacked body LM are provided. At positions distant from each other in the Y direction intersecting with the X direction, the plurality of plate-shaped contacts LI penetrate the insulating layers 52 and 51, the stacked body LM, and the upper source line DSLt and reach the intermediate source line BSL. This way, the stacked body LM is divided in the Y direction by the plurality of plate-shaped contacts LI.

On a side wall of the plate-shaped contact LI, an insulating layer 54 such as a silicon oxide layer is provided. An inside of the insulating layer 54 is filled with a conductive layer 21 such as a tungsten layer. The conductive layer 21 of the plate-shaped contact LI is connected to the upper layer wiring through a plug or the like (not illustrated). In addition, a lower end portion of the conductive layer 21 is connected to the intermediate source line BSL.

With the above-described configuration, the plate-shaped contact LI functions as, for example, a source line contact. It should be noted that, instead of the plate-shaped contact LI, an insulating layer or the like that does not function as the source line contact may divide the stacked body LM in the Y direction.

Between two plate-shaped contacts LI adjacent to each other in the Y direction, the plurality of pillars PL are dispersed in a staggered arrangement, for example, when seen from the stacking direction of the stacked body LM. The pillar PL includes a channel layer CN, a cap layer CP, a memory layer ME, and a core layer CR, penetrates the insulating layer 51, the stacked body LM, the upper source line DSLt, and the intermediate source line BSL, and reaches the lower source line DSLb.

In a center portion of the pillar PL, the core layer CR as a filling layer that extends in the stacking direction of the stacked body LM is provided. An upper end portion of the core layer CR protrudes, for example, from an upper end portion of the channel layer CN into the cap layer CP. The core layer CR is, for example, an insulating layer such as a silicon oxide layer.

The channel layer CN as a semiconductor layer extends in the stacked body LM in the stacking direction of the stacked body LM. More specifically, the channel layer CN covers a side surface and a lower end portion of the core layer CR, extends into the stacked body LM from a height position of the word line WL of at least the uppermost layer of the stacked body LM, and reaches the lower source line DSLb.

The cap layer CP is provided on the channel layer CN, and an upper end portion of the cap layer CP is connected to the bit line BL through plugs CH provided in the insulating layers 53 and 52. That is, the cap layer CP reaches the upper end portion of the channel layer CN from a position higher than the word line WL of the uppermost layer of the stacked body LM.

Each of the channel layer CN and the cap layer CP is a semiconductor layer such as a polysilicon layer or an amorphous silicon layer. Each of the channel layer CN and the cap layer CP may be a layer where the polysilicon and amorphous silicon are mixed. Each of the channel layer CN and the cap layer CP may be a substantially monocrystalline silicon layer.

The memory layer ME is provided on a side surface and a bottom surface of the channel layer CN. More specifically, as illustrated in FIG. 2B, the memory layer ME has a stacked structure in which a block insulating layer BK, a charge storage layer CT, and a tunnel insulating layer TN are stacked in this order from the outer peripheral side of the pillar PL. The block insulating layer BK is, for example, a silicon oxide (SiO₂) layer, the charge storage layer CT is, for example, a silicon nitride (SiN) layer, and the tunnel insulating layer TN is, for example, a silicon oxynitride (SiON) layer.

For example, a nitrogen concentration in the silicon oxynitride layer forming the tunnel insulating layer TN is 10 atm % or more and preferably 11 atm % or more in terms of average value. More specifically, a nitrogen concentration in the tunnel insulating layer TN increases from a channel layer CN side toward a charge storage layer CT side, for example, in a range of 0 atm % or more and 30 atm % or less.

In addition, the tunnel insulating layer TN may include hydrogen. The reason for this is that, for example, hydrogen in source gas or the like of the tunnel insulating layer TN remains in the tunnel insulating layer TN. A hydrogen concentration in the tunnel insulating layer TN decreases, for example, from the channel layer CN side toward the charge storage layer CT side. As a result, the hydrogen concentration in the tunnel insulating layer TN is reduced to be, for example, 1×10²⁰ atm/cc or less in terms of average value. In addition, the tunnel insulating layer TN includes a portion having a hydrogen concentration of more preferably 1×10¹⁹ atm/cc or less.

As described above, the memory layer ME covers the side surface of the channel layer CN, reaches the lower source line DSLb, and also covers a lower end portion of the channel layer CN. It should be noted that the memory layer ME is not provided at a depth position of the intermediate source line BSL in the source line SL, and the intermediate source line BSL is in contact with the channel layer CN. As a result, the side surface of the channel layer CN is connected to the source line SL through the intermediate source line BSL.

With the above-described configuration, the plurality of memory cells MC located at respective height positions of the word lines WL are formed on a side surface of the pillar PL. As described above, by applying a predetermined voltage to the memory cell MC through the word line WL, data is written into or read from the memory cell MC.

That is, when “H” level data is written into the memory cell MC, a write voltage is applied to the word line WL connected to the memory cell MC. At this time, a ground voltage is supplied to the channel layer CN to form a channel, and electrons in the channel come out from the tunnel insulating layer TN and are injected into and stored in the charge storage layer CT. As a result, a threshold voltage Vth of the memory cell MC increases such that the memory cell MC enters a state where the “H” level data is written.

When “L” level data is written into the memory cell MC, a channel of the channel layer CN enters a floating state such that electrons are not injected into the charge storage layer CT and a state where the “L” level data is written with the threshold voltage Vth of the memory cell MC low is maintained.

When data is read from the memory cell MC, a read voltage is applied to the word line WL connected to the memory cell MC. The read voltage is a voltage that causes the memory cell MC storing the “L” level data to be turned on and prevents the memory cell MC storing the “H” level data from being turned on. Accordingly, a cell current flowing through the bit line BL represents that the “L” level data is read, and a cell current not flowing through the bit line BL represents that the “H” level data is read.

When the data written in the memory cell MC is erased, a high voltage is applied to the source line SL to generate holes. In this state, by applying 0 V to the word line WL, the holes are injected into the charge storage layer CT such that the threshold voltage Vth of the memory cell MC can be reduced. As a result, data of all of the memory cells MC between two plate-shaped contacts LI adjacent to each other in the Y direction are erased.

By controlling a voltage to be applied to the word line WL, the peripheral circuit PER (refer to FIG. 1) controls the write operation, the read operation, and the like of the memory cell MC. In addition, the peripheral circuit PER senses the cell current flowing through the bit line BL and reads data from the memory cell MC.

Here, as described above, by adjusting the nitrogen concentration in the tunnel insulating layer TN to be a predetermined value or higher, the valence band barrier of the tunnel insulating layer TN is reduced, and stress during data erasing of the memory cell MC is reduced. That is, erasing characteristics of data in the memory cell MC are improved. In addition, when data erasing stress is reduced, easy leakage of electrons caused by deterioration of the tunnel insulating layer TN due to repeated writing/erasing is reduced, and write endurance of the memory cell MC is improved.

On the other hand, as described above, by adjusting the hydrogen concentration in the tunnel insulating layer TN to be a predetermined value or lower, charge retention characteristics of the memory cell MC in a low and medium field range of, for example, 6 MV/cm or less are improved, and the generation of a leakage current can be reduced. In addition, an increase in the leakage current at a high temperature is reduced such that operating characteristics of the memory cell MC are improved. In addition, temperature dependence of the leakage current is reduced such that an increase in the leakage current caused by a temperature increase is reduced.

For example, in the tunnel insulating layer TN in the memory cell MC according to the embodiment, when the average value of the nitrogen concentration in the tunnel insulating layer TN is 10 atm % or more, the leakage current of the memory cell MC having a field intensity of 5 MV/cm is reduced to be, for example, 3.0×10⁻⁸ A/cm² or less. In addition, when the average value of the nitrogen concentration in the tunnel insulating layer TN is 11 atm % or more, the leakage current of the memory cell MC having the field intensity of 5 MV/cm is reduced to be, for example, 1.6×10⁻⁸ A/cm² or less.

In addition, in another example, in the tunnel insulating layer TN in the memory cell MC according to the embodiment, when the average value of the nitrogen concentration in the tunnel insulating layer TN is 10 atm % or more, in an operation environment where the field intensity is 6 MV/cm and the temperature is 140° C. or higher, the leakage current of the memory cell MC is reduced to be, for example, 4.0×10⁻⁸ A/cm² or less.

### Method of Manufacturing Semiconductor Memory Device

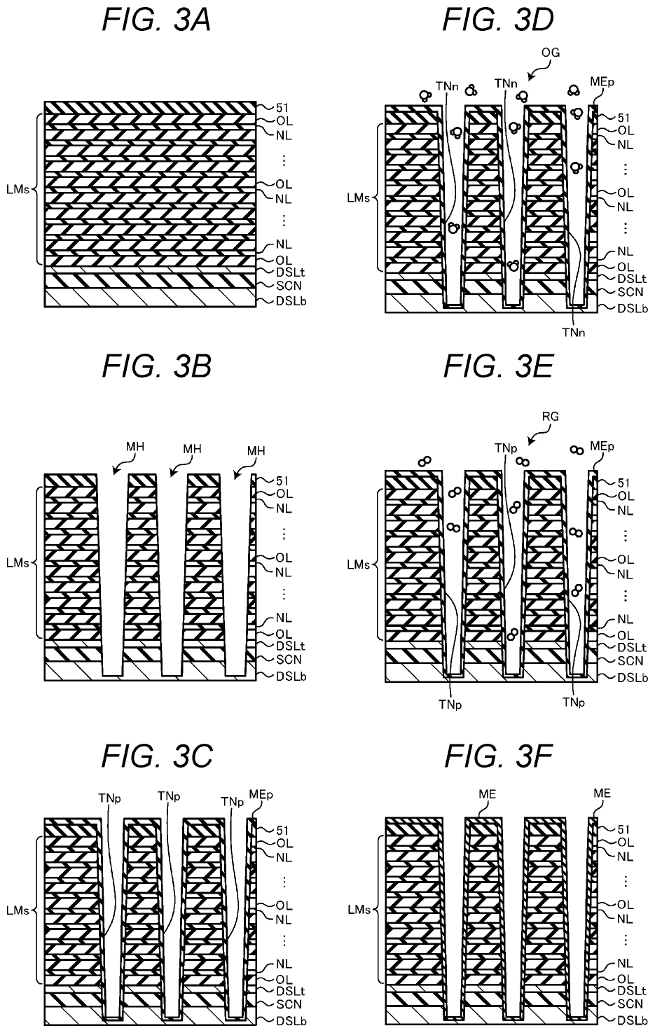

Next, an example of a method of manufacturing the semiconductor memory device 1 according to the embodiment will be described with reference to FIGS. 3A to 5F. FIGS. 3A to 5F are cross-sectional views in the Y direction sequentially illustrating a part of a procedure in the method of manufacturing the semiconductor memory device 1 according to the embodiment.

As illustrated in FIG. 3A, the lower source line DSLb, an intermediate layer SCN, and the upper source line DSLt are formed in this order. The intermediate layer SCN is, for example, a sacrifice layer such as a silicon nitride layer and subsequently is replaced with a conductive polysilicon layer or the like to form the intermediate source line BSL.

In addition, a stacked body LMs in which a plurality of insulating layers NL as first insulating layers and the plurality of insulating layers OL as second insulating layers are stacked one by one alternately is formed on the upper source line DSLt. The insulating layer NL is, for example, a sacrifice layer such as a silicon nitride layer and subsequently is replaced with a tungsten layer or a molybdenum layer to form the word line WL.

In addition, at opposite end portions of the stacked body LMs in the X direction (not illustrated), the plurality of insulating layers NL are processed stepwise. In addition, the insulating layer 51 that covers the stacked body LMs is formed.

As illustrated in FIG. 3B, a plurality of memory holes MH that penetrate the insulating layer 51, the stacked body LMs, the upper source line DSLt, and the intermediate layer SCN and reach the lower source line DSLb are formed.

As illustrated in FIG. 3C, a memory layer MEp where the block insulating layer BK, the charge storage layer CT (refer to FIG. 2B), and a tunnel insulating layer TNp as a first silicon oxynitride layer are stacked in this order is formed on a side wall and a bottom surface of the memory hole MH.

At this time, the tunnel insulating layer TNp in the memory layer MEp is not the tunnel insulating layer TN having the nitrogen concentration and the hydrogen concentration described above. More specifically, the tunnel insulating layer TNp at this time is a silicon oxynitride layer or the like that is formed using silicon source gas, oxidizing gas, nitriding gas, and the like, for example, by atomic layer deposition (ALD) method such that the target nitrogen concentration in the tunnel insulating layer TNp is, for example, 14 atm % and the target layer thickness is several nanometers.

As the silicon source gas, for example, silane gas such as monosilane (SiH₄), dichlorosilane (SiH₂Cl₂), trichlorosilane (SiHCl₃), tetrachlorosilane (SiCl₄), or hexachlorodisilane (Si₂Cl₆) may be used. As the oxidizing gas, for example, oxygen (O₂) gas or water (H₂O) may be used. As the nitriding gas, for example, ammonia (NH₃) gas may be used. By using this gas, the tunnel insulating layer TNp can include hydrogen with a predetermined concentration.

The memory layer MEp is also formed on an upper surface of the insulating layer 51.

As illustrated in FIG. 3D, the tunnel insulating layer TNp on an outermost surface of the memory layer MEp is thermally oxidized such that the target layer thickness of thermal oxidation, that is, the depth of the tunnel insulating layer TNp impregnated with oxygen is 50% to 60% with respect to the total layer thickness of the tunnel insulating layer TNp having a thickness of several nanometers. At this time, the temperature of the thermal oxidation is, for example, 500° C. or higher and 1,000° C. or lower and preferably 700° C. or higher and 900° C. or lower. In addition, as an oxidizer OG of thermal oxidation, for example, water (H₂O) or heavy water (D₂O) can be used.

At this time, the tunnel insulating layer TNp is oxidized from the surface side, and a gradient is generated in the oxygen concentration and the nitrogen concentration in the tunnel insulating layer TNp. That is, the oxygen concentration increases from a surface of the tunnel insulating layer TNp on the charge storage layer CT side toward an outermost surface, and the nitrogen concentration decreases from the surface of the tunnel insulating layer TNp on the charge storage layer CT side toward the outermost surface.

As a result, the tunnel insulating layer TNp is obtained as a second silicon oxynitride layer with a lower overall nitrogen concentration than the state immediately after the formation.

As illustrated in FIG. 3E, a heat treatment is performed on the tunnel insulating layer TNp of the outermost surface of the memory layer MEp in a reducing atmosphere. At this time, the temperature of the heat treatment is a temperature higher than the thermal oxidation temperature and is, for example, 1,000° C. or higher and preferably 1,000° C. or higher and 1,150° C. or lower. In addition, the heat treatment is performed in an atmosphere of reducing gas RG such as hydrogen (H₂) gas or deuterium (D₂) gas as the reducing atmosphere.

Alternatively, the heat treatment may be performed in an atmosphere of chlorine (Cl₂) gas, fluorine (F₂) gas, or ammonia (NH₃) gas as the reducing gas RG. It should be noted that, in order to prevent the tunnel insulating layer TNp from being partially removed and to prevent a decrease in layer thickness, it is preferable to use non-corrosive gas as the reducing gas RG.

In addition, for example, by controlling the flow rate of the reducing gas RG, a pressure during the heat treatment can be adjusted to be, for example, 5 Torr or higher and 550 Torr or lower.

This way, by performing the heat treatment at a temperature higher than the thermal oxidation temperature of FIG. 3D in the reducing atmosphere, the nitrogen concentration in the tunnel insulating layer TNp increases again with respect to the oxygen concentration due to the reduction action of the reducing gas RG, is, for example, 10 atm % or more and preferably 11 atm % or more in terms of average value.

At this time, the gradient of the nitrogen concentration generated by the thermal oxidation is maintained. That is, the nitrogen concentration decreases from the surface of the tunnel insulating layer TNp on the charge storage layer CT side toward the outermost surface, for example, in a range of 0 atm % or more and 30 atm % or less.

In addition, as described below based on data, it is known that, by performing the heat treatment in the reducing atmosphere, the hydrogen concentration incorporated from the source gas and the like during the formation of the tunnel insulating layer TNp decreases. As a result, the tunnel insulating layer TNp has a hydrogen concentration of 1×10²⁰ atm/cc or less in terms of average value and preferably includes a portion having a hydrogen concentration of 1×10²⁰ atm/cc or less.

As illustrated in FIG. 3F, the tunnel insulating layer TN is obtained by the thermal oxidation and the heat treatment described above.

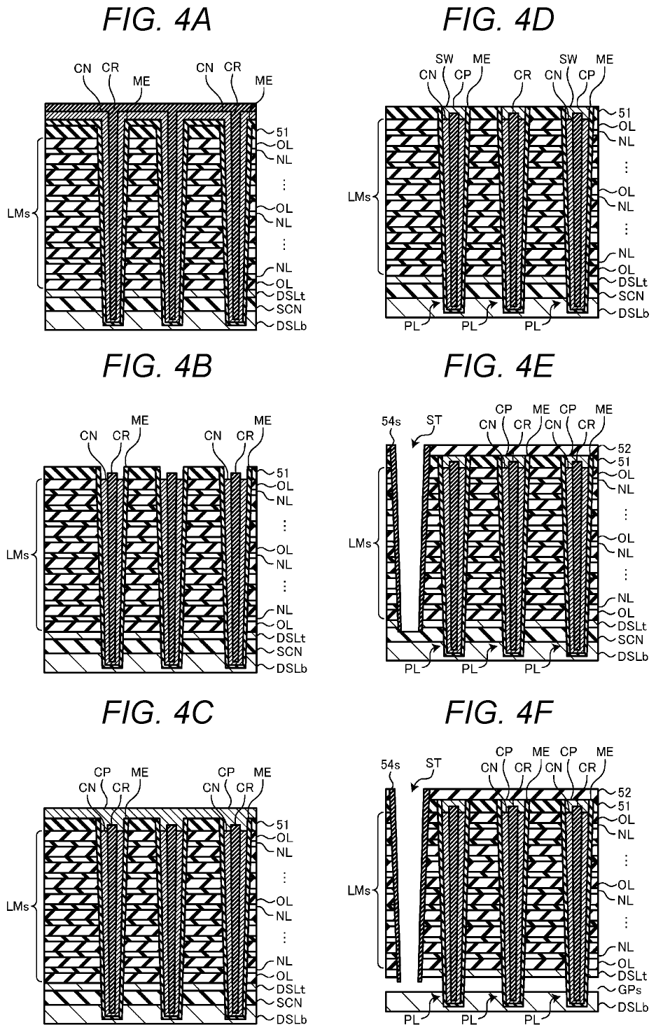

As illustrated in FIG. 4A, the channel layer CN is further formed on the side wall and the bottom surface of the memory hole MH through the memory layer ME. As a result, the channel layer CN is also formed on the upper surface of the insulating layer 51 through the memory layer ME. In addition, the inside of the channel layer CN of the memory hole MH is filled with the core layer CR. The core layer CR is also formed on the upper surface of the insulating layer 51 through the channel layer CN and the memory layer ME.

As illustrated in FIG. 4B, the core layer CR is etched back and removed from the upper surface of the insulating layer 51 and an upper end of the memory hole MH. In addition, the channel layer CN and the memory layer ME are etched back and removed from the upper surface of the insulating layer 51. As a result, the upper surface of the insulating layer 51 is exposed.

At this time, the overetching amount of the channel layer CN is controlled to etch back the channel layer CN even in the memory hole MH. In addition, at this time, the overetching amount of the memory layer ME is controlled to be reduced such that even the memory layer ME in the memory hole MH is not removed. As a result, the upper end portion of the channel layer CN is positioned at a predetermined depth in the memory hole MH such that the core layer CR protrudes from the upper surface of the channel layer CN in the memory hole MH.

As illustrated in FIG. 4C, the cap layer CP that covers the upper surface of the insulating layer 51 is formed. The cap layer CP is also formed on the upper portions of the channel layer CN and the core layer CR in the memory hole MH.

As illustrated in FIG. 4D, the cap layer CP is etched back and removed from the upper surface of the insulating layer 51. In addition, at this time, the overetching amount of the cap layer CP is controlled to be reduced such that even the cap layer CP in the memory hole MH is not removed.

As a result, the pillar PL including the cap layer CP is formed on the upper end portion. It should be noted that, at this time, the entire side surface of the channel layer CN of the pillar PL is covered with the memory layer ME.

As illustrated in FIG. 4E, the insulating layer 52 is formed on the insulating layer 51. In addition, a slit ST that penetrates the insulating layers 52 and 51, the stacked body LMs, and the upper source line DSLt and reaches the intermediate layer SCN is formed. The slit ST also extends in a direction along the X direction in the stacked body LMs. In addition, an insulating layer 54s is formed on a side wall facing in the Y direction of the slit ST.

As illustrated in FIG. 4F, a removing liquid such as hot phosphoric acid is injected from an upper portion of the slit ST to remove the intermediate layer SCN that is exposed to a bottom surface of the slit ST. As a result, a gap GPs is formed between the upper source line DSLt and the lower source line DSLb, and a side surface of the memory layer ME on the outermost periphery of the pillar PL is exposed to an inside of the gap GPs.

At this time, the insulating layer 54s on the side wall of the slit ST prevents the removing liquid from flowing into the stacked body LMs such that the insulating layer NL in the stacked body LMs is not removed.

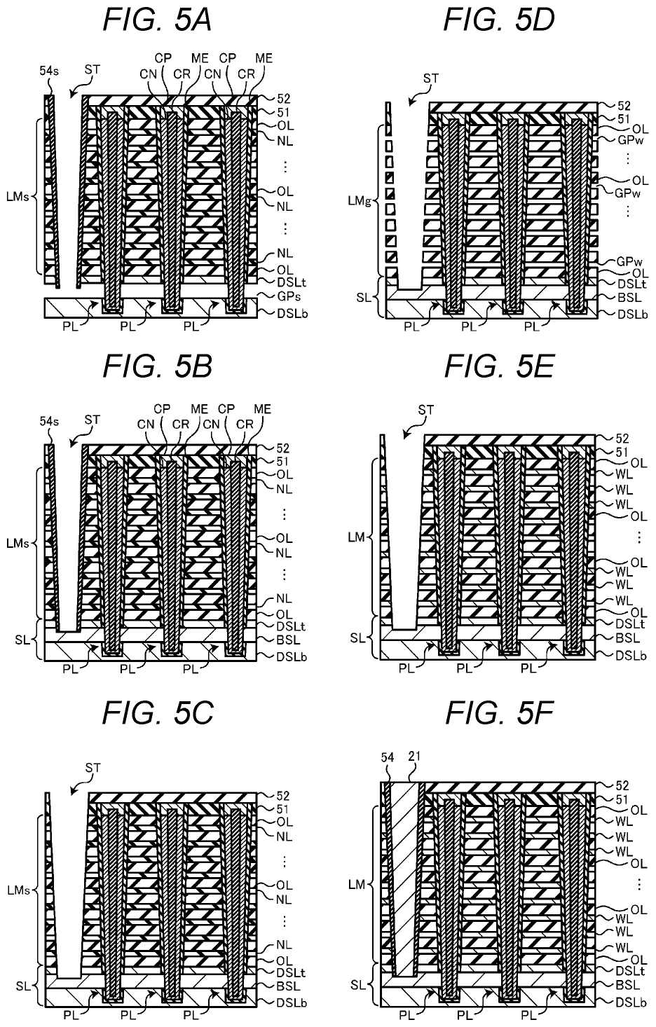

As illustrated in FIG. 5A, a removing liquid that sequentially removes the silicon oxide layer, the silicon nitride layer, the silicon oxynitride layer, and the like is injected from the upper portion of the slit ST such that the block insulating layer BK, the charge storage layer CT, and the tunnel insulating layer TN are removed in order from the outer peripheral side of the memory layer ME exposed to the inside of the gap GPs. As a result, the side surface of the channel layer CN is exposed to the inside of the gap GPs.

As illustrated in FIG. 5B, source gas that is a raw material of the polysilicon is injected from the upper portion of the slit ST such that the inside of the gap GPs is filled with the polysilicon layer or the like to form the intermediate source line BSL.

As a result, the source line SL including the lower source line DSLb, the intermediate source line BSL, and the upper source line DSLt is formed. In addition, the side surface of the channel layer CN of the pillar PL is connected to the source line SL.

As illustrated in FIGS. 4F to 5B, a process of removing the intermediate layer SCN to form the intermediate source line BSL is also called a replacement process of the source line SL.

As illustrated in FIG. 5C, the insulating layer 54s on the side wall of the slit ST is removed.

As illustrated in FIG. 5D, a removing liquid such as hot phosphoric acid is injected from the upper portion of the slit ST to remove the insulating layer NL in the stacked body LMs that is exposed to the side surface of the slit ST. As a result, a stacked body LMg including a gap GPw is formed between the plurality of insulating layers OL.

As illustrated in FIG. 5E, source gas that is a raw material of a conductor or the like is injected from the upper portion of the slit ST such that an inside of the gap GPw is filled with the conductive layer to form the plurality of word lines WL. As a result, the stacked body LM in which the plurality of word lines WL and the plurality of insulating layers OL are stacked alternately is formed.

As illustrated in FIGS. 5D and 5E, a process of removing the insulating layer NL to form the word line WL is also called a replacement process of the word line WL.

As illustrated in FIG. 5F, the insulating layer 54 is formed on the side wall of the slit ST such that the inside of the insulating layer 54 is filled with the conductive layer 21 to form the plate-shaped contact LI. It should be noted that, the entire inside of the slit ST may be filled with the insulating layer to form a plate-shaped member that does not function as the source line contact. In this case, the slit ST is exclusively used in the replacement processes of the source line SL and the word line WL.

Next, the insulating layer 53 is formed on the insulating layer 52 such that the plug CH connected to the cap layer CP of the pillar PL and the bit line BL and the like connected to the plug CH are formed by penetrating the insulating layers 53 and 52.

In addition, the semiconductor substrate 20 having a surface on which the peripheral circuit PER including the transistor TR is formed is prepared (refer to FIG. 1) and is bonded above the stacked body LM. This way, by separately preparing the peripheral circuit PER and integrating the peripheral circuit PER with the memory structure at a final stage of the manufacturing process of the semiconductor memory device 1, the peripheral circuit PER is prevented from being affected by heat generated by the heat treatment in the reducing atmosphere described above.

As a result, the semiconductor memory device 1 according to the embodiment is manufactured.

### SUMMARY

In the semiconductor memory device such as the three-dimensional nonvolatile memory, a plurality of memory cells located in the height direction are formed in a pillar including a channel layer, a tunnel insulating layer, a charge storage layer, and a block insulating layer. At this time, by using the silicon oxynitride layer or the like as the tunnel insulating layer to increase the nitrogen concentration in the layer, the valence band barrier can be reduced, and erasing characteristics and write endurance of data in the memory cell can be improved.

However, when the nitrogen concentration in the tunnel insulating layer increases, the leakage current of the memory cell in the low and medium field range increases, and data retention properties deteriorate. This way, in the memory cell having the above-described configuration, it is difficult to achieve write endurance and charge retention characteristics simultaneously.

The present inventors found that, by forming the tunnel insulating layer by ALD or the like, performing an oxidation treatment in an atmosphere including water vapor or the like, and performing a heat treatment in a reducing atmosphere including hydrogen or the like as a main component, the leakage current in the low and medium field range can be reduced in a state where the nitrogen concentration is high.

The present inventors performed various evaluations on the tunnel insulating layer obtained as described above, and found that the nitrogen concentration increases and the hydrogen concentration decreases after the thermal oxidation, in the tunnel insulating layer. Based on this finding, the present inventors made the following consideration on a mechanism of simultaneously achieving write endurance and charge retention characteristics using the tunnel insulating layer TN according to the embodiment.

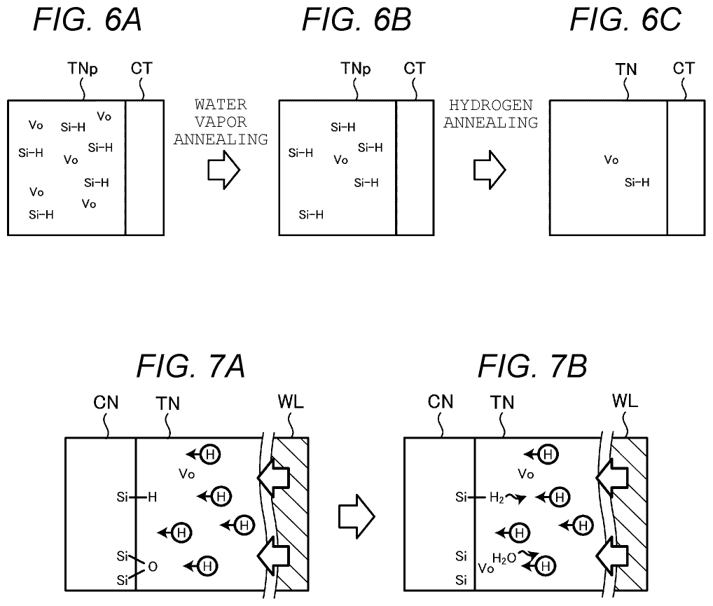

FIGS. 6A to 6C are schematic diagrams illustrating a formation mechanism of the tunnel insulating layer TN according to the embodiment.

As illustrated in FIG. 6A, the tunnel insulating layer TNp is formed on a side wall of the charge storage layer CT by ALD or the like. A left side surface of the tunnel insulating layer TNp with respect to the paper plane is exposed to the inside of the memory hole MH. The tunnel insulating layer TNp is in a state where oxygen defects Vo are present at a predetermined ratio and hydrogen remaining in the tunnel insulating layer TNp is bonded to some silicon bond hands.

As illustrated in FIG. 6B, for example, when the thermal oxidation is performed in an atmosphere including water vapor, the tunnel insulating layer TNp is oxidized at a predetermined ratio such that a part of the oxygen defects Vo in the tunnel insulating layer TNp is repaired.

As illustrated in FIG. 6C, for example, when the heat treatment is performed in an atmosphere including hydrogen gas, hydrogen in the layer decreases, and the tunnel insulating layer TN is formed.

FIGS. 7A and 7B are schematic diagrams illustrating a mechanism when a voltage is applied to the tunnel insulating layer TN according to the embodiment.

As illustrated in FIG. 7A, the channel layer CN or the like is formed on the exposed surface of the tunnel insulating layer TN formed as illustrated in FIG. 6B, and the charge storage layer CT and the block insulating layer BK are separated from the tunnel insulating layer TN by the replacement process to form the word line WL. In the drawing, the charge storage layer CT and the block insulating layer BK are not illustrated.

When an operating voltage of the memory cell is applied from the word line WL, hot carriers (H in a circle in the drawing) are injected into the tunnel insulating layer TN.

As illustrated in FIG. 7B, a part of hydrogen remaining in the tunnel insulating layer TN obtains energy from the hot carriers, and for example, bonding to the silicon bond hand is cut to generate hydrogen molecules. In addition, the hydrogen that obtains the energy from the hot carriers and oxygen in silicon oxide (SiO₂) in the tunnel insulating layer TN are bonded to each other to generate water molecules (H₂O), and bonding between silicon and oxygen is cut to newly generate oxygen defects Vo.

As described above, the hydrogen concentration in the tunnel insulating layer TN according to the embodiment is reduced by the heat treatment in the reducing atmosphere after the thermal oxidation. As a result, it is considered that the amount of new oxygen defects Vo generated by the hot carriers during voltage application can be reduced.

In the semiconductor memory device 1 according to the embodiment, the tunnel insulating layer TN has a hydrogen concentration of 1×10²⁰ atm/cc or less in terms of average value and preferably includes a portion having a hydrogen concentration of 1×10¹⁹ atm/cc or less. As a result, even when the nitrogen concentration in the tunnel insulating layer TN is high, the leakage current of the memory cell MC in the low and medium field range can be reduced. Accordingly, the improvement of erasing characteristics and a reduction in the leakage current of the memory cell MC can be simultaneously achieved.

In the semiconductor memory device 1 according to the embodiment, the nitrogen concentration in the tunnel insulating layer TN is 10 atm % or more and preferably 11 atm % or more in terms of average value. At this time, the nitrogen concentration in the tunnel insulating layer TN increases from the channel layer CN side toward the charge storage layer CT side, for example, in a range of 0 atm % or more and 30 atm % or less. As a result, in the presence of a high nitrogen concentration, write endurance and charge retention characteristics of the memory cell MC can be simultaneously achieved.

In the method of manufacturing the semiconductor memory device 1 according to the embodiment, the tunnel insulating layer TNp is thermally oxidized, and a heat treatment is performed in the reducing atmosphere at a temperature higher than the temperature in the thermal oxidation to form the tunnel insulating layer TN. As a result, the improvement of erasing characteristics and a reduction in the leakage current of the memory cell MC can be simultaneously achieved.

In the method of manufacturing the semiconductor memory device 1 according to the embodiment, the temperature of the thermal oxidation is 500° C. or higher and 1,000° C. or lower and preferably 700° C. or higher and 900° C. or lower. In addition, the temperature of the heat treatment is 1,000° C. or higher and preferably 1,000° C. or higher and 1,150° C. or lower. As a result, in the tunnel insulating layer TNp, the nitrogen concentration is increased and the hydrogen concentration is reduced, and the tunnel insulating layer TN according to the embodiment can be formed.

In the method of manufacturing the semiconductor memory device 1 according to the embodiment, the stacked body LM is bonded to the semiconductor substrate 20 where the peripheral circuit PER including the transistor TR is formed. This way, the peripheral circuit PER is bonded after the heat treatment of the tunnel insulating layer TNp in the reducing atmosphere. Therefore, the peripheral circuit PER can be prevented from being affected by heat.

### EXAMPLES

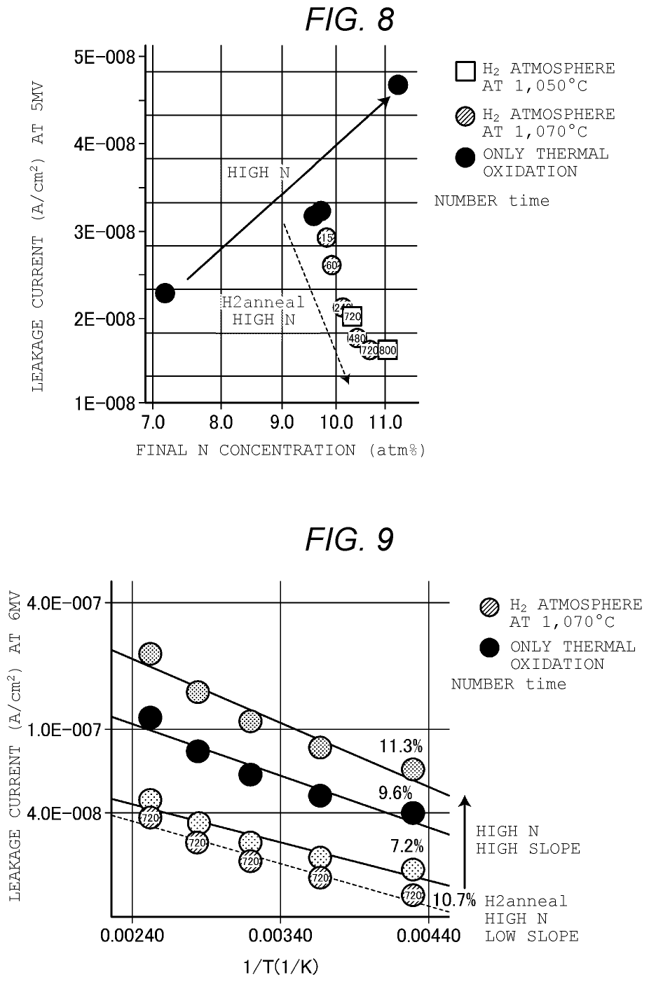

Hereinafter, various evaluation results for a tunnel insulating layer according to Example will be described with reference to FIGS. 8 to 10.

FIG. 8 is a graph illustrating a relationship between each of tunnel insulating layers according to Example and Comparative Example and a leakage current. In the graph of FIG. 8, the horizontal axis represents the average nitrogen concentration (atm %) in each of the tunnel insulating layers according to Example and Comparative Example. In the graph, the vertical axis represents the leakage current (A/cm²) at a field intensity of 5 MV/cm.

As described above in the embodiment, the tunnel insulating layer according to Example is formed by performing the thermal oxidation in the water vapor atmosphere and the heat treatment in the reducing atmosphere after the formation by ALD. That is, water was used as an oxidizer of the thermal oxidation. The nitrogen concentration of the tunnel insulating layer after the thermal oxidation is about 9 atm %.

In addition, the heat treatment was performed at 1,050° C. and 1,070° C. in the hydrogen gas atmosphere. At this time, the heat treatment time was gradually increased to investigate a relationship with the leakage current. In some plots, a numerical value described in a marker represents the treatment time of the heat treatment. That is, a numerical value “15” in a marker represents that the heat treatment time is 15 seconds, and “720” represents that the heat treatment time is 720 seconds (12 minutes).

As illustrated in FIG. 8, in the tunnel insulating layer according to Example, as the heat treatment time increases, the nitrogen concentration in the obtained tunnel insulating layer increases. In addition, for example, the nitrogen concentration when the heat treatment is performed at the heat treatment temperature of 1,050° C. for 720 seconds is substantially the same as that when the heat treatment is performed at the heat treatment temperature of 1,070° C. for 240 seconds. Therefore, as the heat treatment temperature increases, the nitrogen concentration in the tunnel insulating layer can be increased in a shorter period of time.

In addition, as the nitrogen concentration in the tunnel insulating layer according to Example increases due to the heat treatment, the leakage current decreases. For example, in the tunnel insulating layer where the nitrogen concentration is about 10 atm % due to the heat treatment, the leakage current decreases to about 3.0×10⁻⁸ A/cm². Further, in the tunnel insulating layer where the nitrogen concentration is about 11 atm %, the leakage current decreases to about 1.6×10⁻⁸ A/cm².

Meanwhile, the tunnel insulating layer according to Comparative Example was formed by performing the thermal oxidation under the same conditions as those of Example without performing the heat treatment in the reducing atmosphere. At this time, for example, by changing the time of the thermal oxidation, the nitrogen concentration in the tunnel insulating layer was changed to investigate a relationship with the leakage current.

In the tunnel insulating layer according to Comparative Example, as the nitrogen concentration in the layer increases, the leakage current increases. For example, in the tunnel insulating layer where the nitrogen concentration is about 7 atm %, the leakage current is about 2.4×10⁻⁸ A/cm². In the tunnel insulating layer where the nitrogen concentration is about 9 atm %, the leakage current increases to about 3.4×10⁻⁸ A/cm². Further, in the tunnel insulating layer where the nitrogen concentration is about 11 atm %, the leakage current increases to about 4.8×10⁻⁸ A/cm².

It was found from the above results that, when the tunnel insulating layer is formed by performing only the thermal oxidation as in the tunnel insulating layer according to Comparative Example, as the nitrogen concentration in the layer increases, the leakage current increases. On the other hand, it was found that, when the nitrogen concentration in the tunnel insulating layer is reduced by the thermal oxidation and subsequently is increased again by the heat treatment in the reducing atmosphere as in the tunnel insulating layer according to Example, the leakage current can be reduced.

This way, in the tunnel insulating layer according to Example where the nitrogen concentration was increased to the same as that of the tunnel insulating layer according to Comparative Example, the leakage current was able to be sufficiently reduced.

FIG. 9 is a graph illustrating a relationship between the leakage current of each of the tunnel insulating layers according to Example and Comparative Example and a temperature. In the graph of FIG. 9, the horizontal axis represents the inverse of the temperature 1/T (1/K), and In the graph, the vertical axis represents the leakage current (A/cm²) at a field intensity of 6 MV/cm.

The tunnel insulating layer according to Example is formed by performing the thermal oxidation in the water vapor atmosphere and the heat treatment in the reducing atmosphere after the formation by ALD. That is, water was used as an oxidizer of the thermal oxidation. In addition, the heat treatment was performed at 1,070° C. in a hydrogen gas atmosphere. The nitrogen concentration of the tunnel insulating layer after the heat treatment is about 10.7 atm %.

In plots, a numerical value described in a marker represents the treatment time of the heat treatment. That is, “720” in a marker represents that the heat treatment time is 720 seconds (12 minutes).

As illustrated in FIG. 9, in the tunnel insulating layer according to Example, the leakage current can be reduced to be 4.0×10⁻⁸ A/cm² or less in a temperature range of about −45° C. to 140° C.

Meanwhile, the tunnel insulating layer according to Comparative Example was formed by performing the thermal oxidation under the same conditions as those of Example without performing the heat treatment in the reducing atmosphere. At this time, for example, by changing the time of the thermal oxidation, the nitrogen concentration in the tunnel insulating layer was changed to obtain tunnel insulating layers according to Comparative Example where the nitrogen concentrations were 7.2 atm %, 9.6 atm %, and 11.3 atm %, respectively.

In the tunnel insulating layer according to Comparative Example, when the nitrogen concentration was 11.3 atm %, the leakage current at about 140° C. was about 2.8×10⁻⁷ A/cm², and when the nitrogen concentration was 9.6 atm %, the leakage current at about 140° C. was about 1.0×10⁻⁷ A/cm². In addition, only when the nitrogen concentration was reduced to 7.2 atm %, the leakage current at about 140° C. was reduced to 4.0×10⁻⁸ A/cm² or lower which was the same as that of Example.

Further, in the tunnel insulating layer according to Comparative Example, there was a tendency that, as the nitrogen concentration increases, the temperature dependence of the leakage current increases, and the inclination of the leakage current with respect to the inverse of the temperature becomes steep.

It was found from the above results that, when the tunnel insulating layer is formed by performing only the thermal oxidation as in the tunnel insulating layer according to Comparative Example, as the nitrogen concentration increases, the temperature dependence of the leakage current increases and the leakage current in a high temperature environment increases.

On the other hand, it was found that, when the nitrogen concentration in the tunnel insulating layer is reduced by the thermal oxidation and subsequently is increased again by the heat treatment in the reducing atmosphere as in the tunnel insulating layer according to Example, the tunnel insulating layer where the temperature dependence of the leakage current is low and the inclination of the leakage current with respect to the inverse of the temperature is gentle can be obtained. In addition, it was found that an increase in leakage current can be reduced even in a high temperature environment.

This way, it was found that, in the tunnel insulating layer according to Example where the nitrogen concentration was increased to the same as that of the tunnel insulating layer according to Comparative Example, the reliability at a high temperature can also be improved.

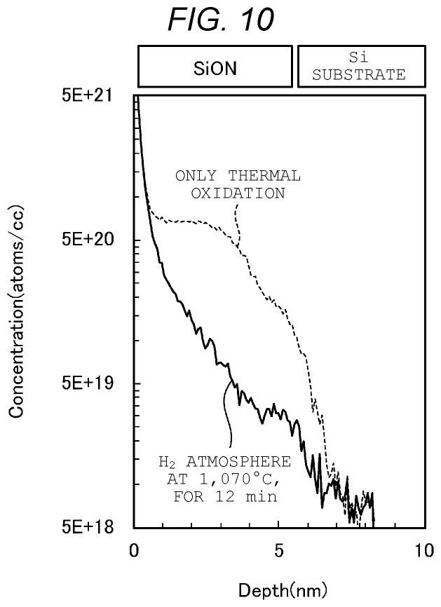

FIG. 10 is a graph illustrating a hydrogen content in a silicon oxynitride layer simulating each of the tunnel insulating layers according to Example and Comparative Example. In the graph of FIG. 10, the horizontal axis represents a depth (nm) from an outermost surface of the silicon oxynitride layer. In the graph, the vertical axis represents the hydrogen concentration (atm/cc) in the silicon oxynitride layer.

As illustrated in FIG. 10, each of the silicon oxynitride layers according to Example and Comparative Example is formed on a silicon substrate having a thickness of 5.5 nm.

The silicon oxynitride layer according to Example is formed by performing the thermal oxidation in the water vapor atmosphere and the heat treatment in the reducing atmosphere after the formation by ALD. That is, water was used as an oxidizer of the thermal oxidation. In addition, the heat treatment was performed at 1,070° C. in a hydrogen gas atmosphere for 12 minutes.

In the silicon oxynitride layer according to Example, the hydrogen concentration that is 5×10²¹ atm/cc or more on the outermost surface instantaneously decreases to about 5×10²⁰ atm/cc at a depth of about 0.5 nm from the surface, and subsequently decreases continuously to about 2.5×10¹⁹ atm/cc in the vicinity of an interface with the silicon substrate.

The tunnel insulating layer according to Comparative Example was formed by performing only the thermal oxidation under the same conditions as those of Example without performing the heat treatment in the reducing atmosphere. In the tunnel insulating layer according to Comparative Example, the hydrogen concentration at a depth of about 0.5 nm from the outermost surface has substantially the same profile as that of Example. However, the hydrogen concentration is maintained to be substantially constant at a depth of about 0.5 nm to 3 nm, decreases again at a depth of 3 nm or more, and is about 1.0×10²⁰ atm/cc in the vicinity of an interface with the silicon substrate.

It was found from the above results that the hydrogen concentration in the silicon oxynitride layer is reduced by performing the heat treatment in the reducing atmosphere as in the silicon oxynitride layer according to Example. It is considered that such a profile of the hydrogen concentration contributes to various characteristics of the tunnel insulating layer TN according to the embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body having a plurality of conductive layers and a plurality of insulating layers alternately stacked one by one; and
a pillar extending in the stacked body in a stacking direction of the stacked body, the pillar including a memory cell formed at each of intersections with the plurality of conductive layers, wherein
the pillar includes:
a semiconductor layer extending in the stacking direction,
a silicon oxynitride layer extending along a side wall of the semiconductor layer,
a silicon nitride layer extending along a side wall of the silicon oxynitride layer, and
a silicon oxide layer extending along a side wall of the silicon nitride layer, wherein
the silicon oxynitride layer has an average hydrogen concentration of 1×10²⁰ atm/cc or less.

2. The semiconductor memory device according to claim 1, wherein a nitrogen concentration in the silicon oxynitride layer is in a range of 0 atm % or more and 30 atm % or less.

3. A method of manufacturing a semiconductor memory device, comprising:
forming a first stacked body having a plurality of first insulating layers and a plurality of second insulating layers alternately stacked one by one;
forming a hole extending in the first stacked body in a stacking direction of the first stacked body;
forming a silicon oxide layer on a side wall of the hole;
forming a silicon nitride layer on the side wall of the hole to cover the silicon oxide layer;
forming a silicon oxynitride layer on the side wall of the hole to cover the silicon nitride layer; and
forming a semiconductor layer on the side wall of the hole to cover the silicon oxynitride layer, wherein
the forming the silicon oxynitride layer includes
forming a first silicon oxynitride layer on the side wall of the hole to cover the silicon nitride layer,
thermally oxidizing the first silicon oxynitride layer to form a second silicon oxynitride layer, and
performing a heat treatment on the second silicon oxynitride layer in a reducing atmosphere at a temperature higher than a temperature of the thermal oxidation.

4. The method of manufacturing a semiconductor memory device according to claim 3, wherein the heat treatment of the second silicon oxynitride layer is performed under an atmosphere of hydrogen or deuterium.

5. The method of manufacturing a semiconductor memory device according to claim 3, wherein the thermal oxidation of the first silicon oxynitride layer is performed using water or heavy water as an oxidizer.

6. The method of manufacturing a semiconductor memory device according to claim 3, wherein
the temperature of the thermal oxidation is 500° C. or higher and 1,000° C. or lower, and
the temperature of the heat treatment is 1,000° C. or higher.

7. The semiconductor memory device according to claim 1, wherein the plurality of conductive layers include word lines.

8. The semiconductor memory device according to claim 1, wherein the plurality of conductive layers are formed of at least tungsten or molybdenum.

9. The semiconductor memory device according to claim 1, wherein the semiconductor memory device includes a three-dimensional nonvolatile memory.

10. The semiconductor memory device according to claim 1, wherein the silicon oxide layer is a block insulating layer.

11. The semiconductor memory device according to claim 1, wherein the silicon nitride layer is a charge storage layer.

12. The semiconductor memory device according to claim 1, wherein the silicon oxynitride layer is a tunnel insulating layer.

13. The semiconductor memory device according to claim 1, wherein the silicon oxynitride layer has a hydrogen concentration of 1×10¹⁹ atm/cc or less in terms of average value.

14. The semiconductor memory device according to claim 2, wherein the nitrogen concentration in the silicon oxynitride layer is in a range of 10 atm % or more.
